(19) United States
(12) Patent Application Publication
(10) Pub. No.: US 2026/0314381 A1
(43) Pub. Date: Oct. 8, 2026

(54) SEMICONDUCTOR DEVICE

(71) Applicant: Fujian Jinhua Integrated Circuit Co., Ltd., Fujian (CN)

(72) Inventors: Yidan ZHANG, Fujian (CN); Yifei YAN, Fujian (CN); Anping ZENG, Fujian (CN); Jianshan WU, Fujian (CN); Erpeng ZHUANG, Fujian (CN)

(73) Assignee: Fujian Jinhua Integrated Circuit Co., Ltd., Fujian (CN)

(21) Appl. No.: 19/641,539

(22) Filed: Apr. 8, 2026

(30) Foreign Application Priority Data
Apr. 8, 2025 (CN) 202520646405.6

(51) Int. Cl. H10W 20/43; H10B 12/00; H10W 20/45

(52) U.S. Cl. CPC H10W 20/43; H10B 12/30; H10W 20/45

(57) ABSTRACT

The application provides a semiconductor device applied to semiconductor technical field. In the application, insulating capping layer structures are arranged in some components of the semiconductor device, respectively, and portions of the insulating capping layer structures extend into the components, respectively, thereby proposing a new structure and improving the reliability and performance of semiconductor devices.

### CROSS-REFERENCE TO RELATED APPLICATION

This application claims priority to Chinese Patent Application No. 202520646405.6, filed on Apr. 08, 2025, which is hereby incorporated by reference in its entirety.

### BACKGROUND

### Technical Field

The application relates to semiconductor technical field, and particularly relates to a semiconductor device.

### Description of Related Art

Dynamic random access memory (DRAM) is a volatile memory, including an array area composed of a plurality of memory cells and a periphery area composed of a control circuit. Each memory cell includes a transistor electrically connected to a capacitor; the transistor controls storing or releasing charges in the capacitor to achieve data storage. The control circuit can locate, through word lines (WL) and bit lines (BL) that span the array area and are electrically connected to respective memory cells, each memory cell to control data access.

### SUMMARY

The purpose of the application is to provide a semiconductor device to improve efficiency and reliability of semiconductor devices.

To solve the above technical problem, the application provides a semiconductor device, including:

a substrate;

a plurality of bit lines, arranged on the substrate and spaced apart from each other along a horizontal direction;

a plurality of spacers, located on side walls of the bit lines respectively;

a plurality of insulating capping layer structures, covering the plurality of bit lines and the spacers, where each insulating capping layer structure includes a first portion arranged on the bit line and at least one second portion located within the spacer;

a plurality of pad structures, each pad structure located between adjacent bit lines, cover a portion of a side wall of the spacers, and the pad structures in direct contact with a top surface of the insulating capping layer structure.

In an embodiment, the spacer may include a first spacer, a second spacer, and a third spacer that are arranged in sequence, and the second portion of the insulating capping layer structure is located between the first spacer and the third spacer, and in direct contact with a top surface of the second spacer.

In an embodiment, a top surface of the first spacer and/or the third spacer may be higher than the top surface of the second spacer.

In an embodiment, a material of the insulating capping layer structure and a material of the third spacer may be the same.

In an embodiment, an outer edge of the insulating capping layer structure and an outer edge of the spacer may be aligned in a vertical direction.

In an embodiment, the semiconductor device may further include:

a plurality of isolation structures, each isolation structure arranged between adjacent pad structures and in direct contact with the insulating capping layer structures and the spacers.

In an embodiment, at least one of the isolation structures may be in direct contact with a top surface of the second portion of the insulating capping layer structure.

In an embodiment, a bottom surface of at least one of the isolation structures may be lower than a bottom surface of the insulating capping layer structure with which the isolation structure is in direct contact.

In an embodiment, bottom surfaces of a plurality of second portions in the same insulating capping layer structure may be located at different horizontal levels.

In an embodiment, a width of the insulating capping layer structure in the horizontal direction may be greater than a width of the bit line in the horizontal direction.

As described above, the semiconductor device of the present application includes a plurality of spacers located on side walls of a plurality of bit lines, and insulating capping layer structures covering the plurality of bit lines and the spacers, where the insulating capping layer structure includes a first portion arranged on the bit line and at least a second portion located in the spacer, thereby proposing a new structure of the semiconductor device and achieving the objective of improving both the efficiency and reliability of the semiconductor device.

### BRIEF DESCRIPTION OF THE DRAWINGS

FIGS. 1 to 6 are schematic structural diagrams of a semiconductor device during respective steps of a manufacturing process provided in an embodiment of the present application.

FIG. 7 is an example of a partially enlarged view of the structure shown in FIG. 6 according to an embodiment of the present application.

FIG. 8 is an example of a partially enlarged view of the structure shown in FIG. 6 according to an embodiment of the present application.

### DESCRIPTION OF THE EMBODIMENTS

To describe the technical solutions and advantages of the embodiments of the present application more clearly, the technical solutions of the present application will be described in further detail below with reference to the accompanying drawings and embodiments. Although the drawings illustrate exemplary embodiments of the present application, it should be understood that the present application may be implemented in various forms and should not be limited to the embodiments described herein. Rather, these embodiments are provided to facilitate a more thorough understanding of the present application and to convey the full scope of the present application to those skilled in the art.

The present application is described in greater detail by way of examples in the following paragraphs, with reference to the accompanying drawings. The advantages and features of the present application will become clearer from the following description and the claims. It should be noted that the drawings are highly simplified and not drawn to exact scale, merely to conveniently and clearly assist in illustrating the purpose of the embodiments of the present application. It is to be understood that the terms “on”, “over”, and “above” in the present application should be interpreted in the broadest manner, so that “on” in the embodiments of the present application not only means being “on” something with no intervening features or layers therebetween (i.e., directly on something), but also includes being “on” something with intervening features or layers therebetween. Terms such as “first”, “second”, etc. are used to distinguish similar objects and are not necessarily used to describe a specific order or sequence. It should be noted that the technical solutions recorded in the embodiments of the present application can be combined arbitrarily without conflict.

It should be particularly noted that the embodiments of the present application relate to top surfaces (top) and bottom surfaces (bottom) of different components or devices, and for convenience of description, a surface of a component or device that is close to a surface of a substrate is referred to as a bottom surface (bottom), and a surface of the component or device that is away from the same surface of the substrate is referred to as a top surface (top) in the following embodiments.

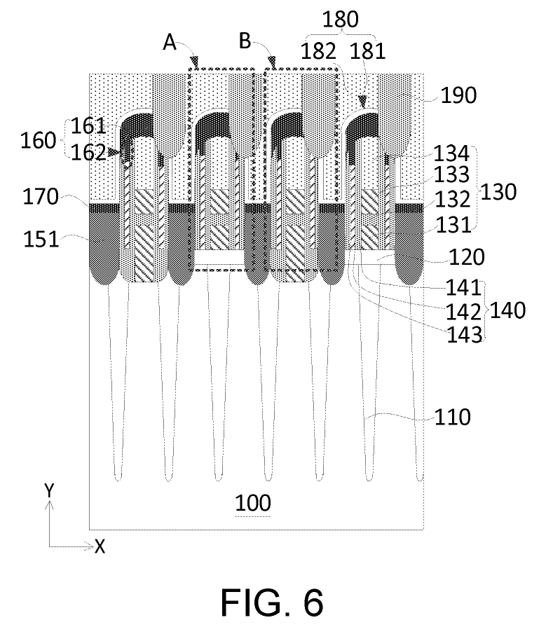

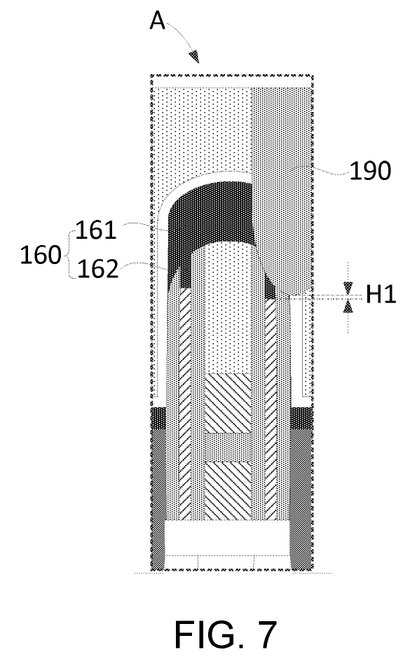

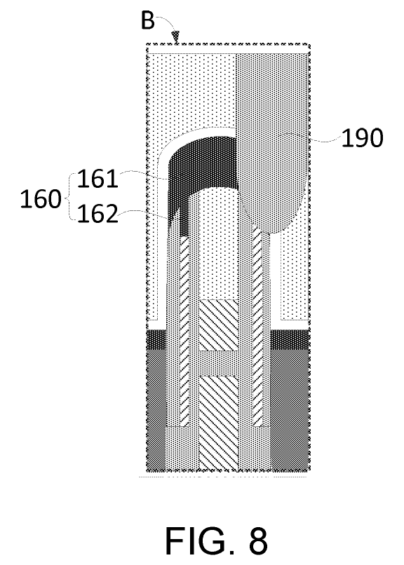

Please refer to FIGS. 6 to 8, which illustrate a schematic diagram of a semiconductor device in one embodiment of the present application and enlarged views of its corresponding different parts; where FIG. 6 is a partial cross-sectional view of a semiconductor device according to an embodiment of the present application; FIG. 7 is an example of a partially enlarged view of the structure shown in FIG. 6 according to an embodiment of the present application, and FIG. 8 is an example of a partially enlarged view of the structure shown in FIG. 6 according to an embodiment of the present application. The semiconductor device of the application can be used in the manufacture of dynamic random access memory (DRAM), and the application can also be applied to other types of memory without departing from the application.

As shown in FIG. 6, a semiconductor device according to an embodiment of the present application includes a substrate 100, a plurality of trench isolations 110, an isolation layer 120, a plurality of bit lines 130, a plurality of spacers 140, a plurality of contact structures 151, a plurality of insulating capping layer structures 160, a silicide layer 170, a plurality of pad structures 180, and a plurality of isolation structures 190.

Specifically, a plurality of trench isolations 110 arranged within the substrate 100 and spaced apart from each other; the trench isolations 110 define a plurality of active regions (not shown) on the substrate 100; and the isolation layer 120 may also be provided on the surface of the substrate 100. In one embodiment, the trench isolation 110 is formed by, for example, forming a plurality of trenches (not shown) in the substrate 100 by etching, and then filling the trenches with one or more layers of an insulating material (such as silicon oxide, silicon nitride or silicon oxynitride), but is not limited thereto. The isolation layer 120 provided on the substrate 100 may be a single layer structure, such as a silicon oxide layer, a silicon nitride layer, and a silicon oxynitride layer, or may be a composite structure, such as an Oxide-Nitride-Oxide (ONO) stacked structure, but is not limited thereto. The isolation layer 120 is formed by, for example, at least one of processes of physical vapor deposition, chemical vapor deposition, atomic layer deposition, etc. The substrate 100 is any suitable substrate material known in the art, such as, a silicon substrate, a silicon-containing substrate (such as SiC, SiGe), a silicon-on-insulator substrate, or a substrate made from other suitable materials.

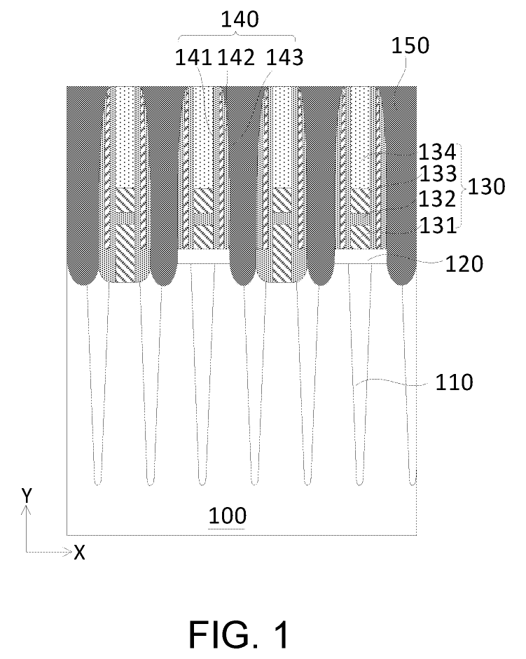

Furthermore, a plurality of bit lines 130 may be arranged on the substrate 100, spaced apart sequentially along a direction parallel to the surface of the substrate 100 (hereinafter referred to as the horizontal direction, i.e. the X-direction in FIG. 6), and bit line plugs extending into the substrate 100 are provided below the bit lines 130. In one embodiment, top surfaces of the plurality of bit lines 130 are not parallel to the extension direction of the horizontal direction (X-direction), or, it may be understood that contours of the top surfaces of the bit lines 130, which protrude in a direction facing away from the surface of the substrate 100, are semi-arc shapes or other irregular shapes, but this is not limited thereto. For example, the formation of the bit lines 130 and the bit line plugs below them is as follows. First, a plurality of trenches (not shown) are formed in the isolation layer 120 and the substrate 100 by etching. Then a semiconductor layer 131 (the underlying material layer of the bit line material layer 130) is formed on the insulating layer 120, and the semiconductor layer 131 fills the trenches and extends laterally to cover the insulating layer 120 between adjacent trenches. Then a barrier layer 132, a metal layer 133 and an insulating layer 134 are formed in sequence from bottom to top, thereby forming the bit line material layer for preparing the plurality of bit lines 130. Then the bit line material layer is etched by using an etching process, such as at least one of wet etching or dry etching, thereby forming the plurality of bit lines 130 spaced apart sequentially on the substrate 100 along the horizontal direction from left to right, where a part of the semiconductor layer 131 filled within the trenches is defined as the bit line plugs for the corresponding bit lines 130, as shown in FIG. 1. Then, along the spacers 140 formed thereafter, portions of the bit lines 130 and the spacers 140 in the height direction are etched along the vertical direction (Y-direction) and removed. Where, the material of the semiconductor layer 131 may include, but is not limited to, crystalline silicon, poly silicon, amorphous silicon, doped silicon, silicon germanium (SiGe), or other suitable semiconductor materials. The material of the barrier layer 132 may include, but is not limited to, a metal, a metal silicide, or a metal nitride, such as titanium (Ti), titanium nitride (TiN), tungsten silicide (WSi), cobalt silicide (CoSi), tungsten nitride (WN). The material of the metal layer 133 may include, but is not limited to, tungsten (W), copper (Cu), aluminum (Al), titanium (Ti), tantalum (Ta), or a compound, an alloy, and/or a composite layer of the foregoing metal materials. The material of the insulating layer 134 may include, but is not limited to, a dielectric material such as silicon oxide (SiO₂), silicon nitride (SiN), silicon oxynitride (SiON), silicon carbonitride (SiCN), or a combination of the foregoing metal materials. For example, the material of the semiconductor layer 131 is polysilicon, the material of the barrier layer 132 is titanium nitride (TiN), the material of the metal layer 133 is tungsten (W), and the material of the insulating layer 134 is silicon nitride (SiN).

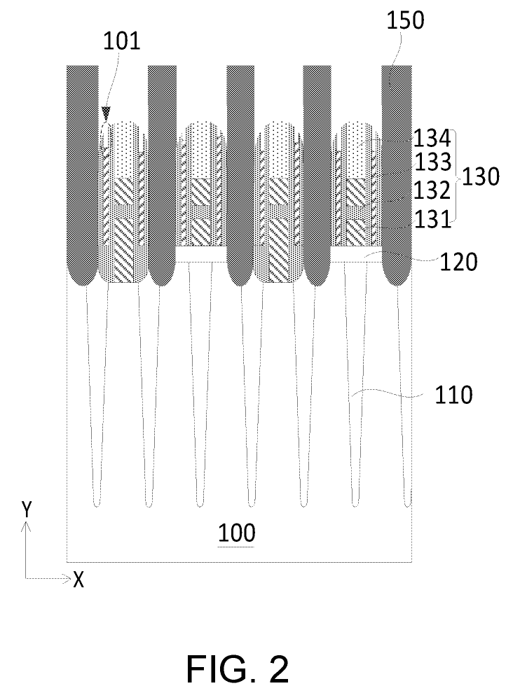

Furthermore, a plurality of spacers 140 may be located on the side walls of both sides of a plurality of bit lines 130 respectively, and inserted vertically (in the Y-direction) into the trenches at both sides of the bit line plugs below the corresponding bit lines 130. The spacer 140 may be a single-layer structure, such as an oxide layer (its material is such as silicon dioxide) or a nitride layer (its material is such as silicon nitride), or it may be a composite structure, for example including a first spacer 141, a second spacer 142 and a third spacer 143 arranged sequentially in the horizontal direction, as shown in FIG. 1. Where the first spacer 141 is in direct contact with one side wall of the bit line 130, the second spacer 142 is located on the surface of the first spacer 141, and the third spacer 143 is located on the surface of the second spacer 142, such that the first spacer 141, second spacer 142, and the third spacer 143 are arranged sequentially from right to left. The contact structure 151 is located in the lower part of the gap between adjacent spacers 140 and extends into the substrate 100 in a direction perpendicular to the surface of the substrate 100 (hereinafter referred to as the vertical direction, i.e. the Y-direction in FIG. 6). In one embodiment, the top surface of the first spacer 141, the top surface of the second spacer 142 and the top surface of the third spacer 143 of the spacer 140 may not be flush (may located at different horizontal levels). For example, as shown in FIGS. 2 to 6, the top surface of the first spacer 141 of the spacer 140 is the highest, the top surface of the second spacer 142 is the lowest; that is, the top surface of the first spacer 141 is higher than the top surface of the second spacer 142 and the top surface of the third spacer 143; the top surface of the second spacer 142 is lower than the top surface of the first spacer 141 and the top surface of the third spacer 143 that are located on both sides of the second spacer 142. As the second spacer 142 is located at the intermediate position within the three-layer composite structure of the spacer 140, this results in the overall shape of the spacer 140 being concave shape, but this is not limited thereto. The top surface of the contact structure 151 may be lower than the top surface of the spacer 140, that is, lower than the top surface of the second spacer 142, which is the lowest top surface within the spacer 140. The material of the contact structure 151 may be phosphorus-doped silicon (SiP), but is not limited thereto.

For example, the formation of the spacers 140 and the contact structures 151 is as follows. The first spacer 141 (for example, the material is silicon oxide), the second spacer 142 (for example, the material is silicon nitride) and the third spacer 143 (for example, the material is silicon oxide) are formed by sequentially and conformally depositing the respective materials onto the inner surface of the gap between adjacent bit lines 130. Then, the material of the first spacer 141, the material of the second spacer 142, and the material of the third spacer 143 are etched away down to the bottom of the gap between adjacent bit lines 130 to expose the top surface of the isolation layer 120 at the bottom of the gap between adjacent spacers 140, as shown in FIG. 1. Then, portions of the substrate 100 between adjacent spacers 140 are removed in the height direction by using an etching process, such as a dry etching process, to form a plurality of trenches (not shown). Then, a contact material layer 150 (a conductive material), such as phosphorus-doped silicon, titanium and/or titanium nitride (TiN), tantalum (Ta) and/or tantalum nitride (TaN), fills the trenches and gaps between adjacent spacers 140 until the top surface of the filled contact material layer 150 is flush with each top surface of each bit line 130 at both sides of the contact material layer 150, as shown in FIG. 1, where, as shown in FIG. 6, the contact structure 151 may be a single-layer structure including the contact material layer 150, or may include a composite structure with multiple layers, such as two layers of contact material layers 150, but is not limited thereto. Then, in the height direction, a portion of the spacer 140 on at least one side of at least one bit line 130 is removed downwards in the vertical direction (Y-direction) by using an etching process, such as dry etching. And at the same time, three layers of spacers, the top surfaces of which are not flush, of the spacer 140 remaining on the side wall of the bit line 130 collectively enclose a recess 101, as shown in FIG. 2. In this process (from the process of FIGS. 1 to 2), due to the top surface of the contact material layer 150 is flush with each top surface of each bit line 130 (before a portion is removed by etching) and each top surface of each spacer 140 (before a portion is removed by etching), the etching process of this step can utilize the contact material layer 150 for self-alignment to remove a portion of the spacer 140 in the height direction and a portion of the bit line 130 in the height direction, but is not limited thereto.

Furthermore, insulating capping layer structures 160 cover the plurality of bit lines 130 and the spacers 140 on the side walls of the plurality of bit lines 130, respectively, and extends vertically (in the Y-direction) to fill the recesses 101 within the corresponding spacers 140, where their (insulating capping layer structures 160) outer edges are aligned vertically (in the Y-direction) with the outer edges of the corresponding spacers 140. In one embodiment, the insulating capping layer structure 160 arranged on the bit line 130 may be defined as a first portion 161, and the insulating capping layer structure 160 arranged within the spacer 140 on the side wall of the bit line 130 may be defined as a second portion 162. In this way, the bottom of the second portion 162 of the insulating capping layer structure 160 is in direct contact with the top surface of the second spacer 142 of the corresponding spacer 140. For example, the material of the insulating capping layer structure 160 may be the same as that of the third spacer 143 in the corresponding spacer 140 (for example, the material is silicon oxide), but is not limited thereto. Furthermore, the contour of the upper surface of the insulating capping layer structure 160 may be the same as the shape of the bit line 130 and the spacer 140 located below it, for example, a half-arc shape protruding away from the surface of the substrate 100.

In one embodiment, as shown in FIG. 6, there may be two second portions 162 in the insulating capping layer structure 160 located on one bit line 130 and the spacers 140 on the side walls of the bit line 130, and the two second portions 162 are located in (or extend into) the spacers 140 on both sides of the bit line 130, respectively. While in other embodiments, the insulating capping layer structure 160 located on one bit line 130 and the spacers 140 on both side walls of the bit line 130 may also have only one second portion 162, i.e., the second portion 162 extending into the spacer 140 on only one side of the bit line 130 is provided, but this is not limited thereto. Furthermore, the bottom surfaces of the two second portions 162 in the insulating capping layer structure 160, which is located on the bit line 130 and the spacers 140 on both side walls of the bit line 130, may be at different horizontal levels or at the same horizontal level. It should be understood that the insulating capping layer structure 160 in the embodiment of the present application needs to have a second portion 162 that fills in the spacer 140, so that the width of the insulating capping layer structure 160 in the horizontal direction (X direction) is larger than the width of the corresponding bit line 130 in the horizontal direction (X direction).

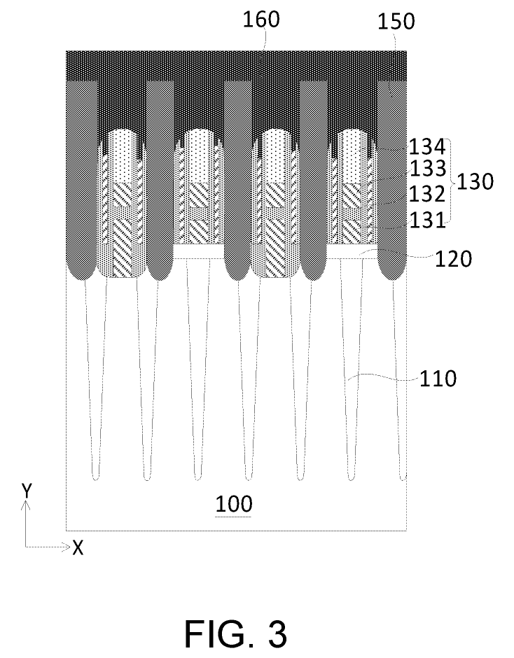

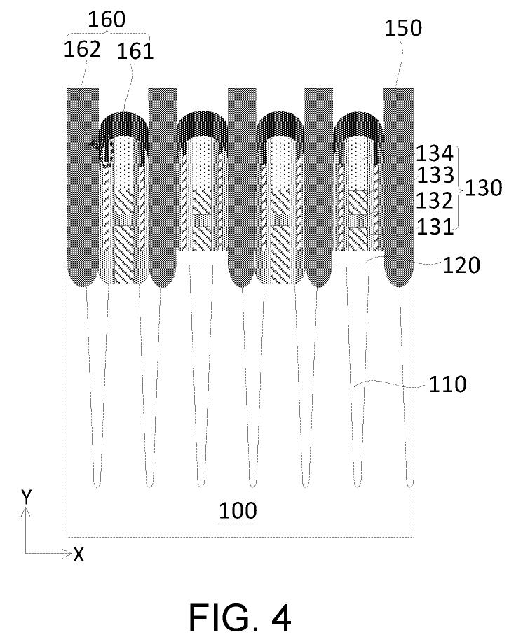

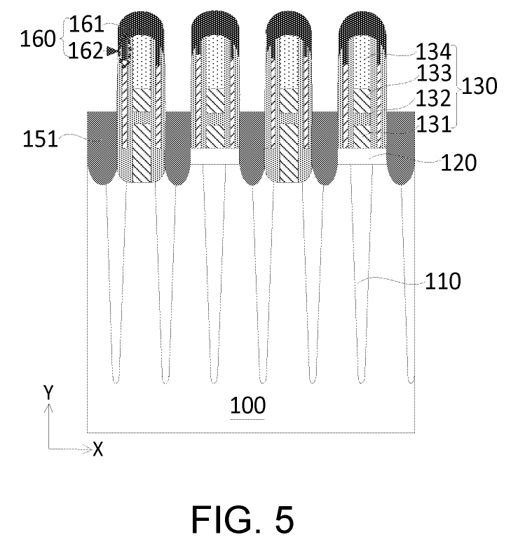

For example, the insulating capping layer structure 160 is formed by using, for example, a deposition process, such as at least one of physical vapour deposition, chemical vapour deposition or atomic layer deposition. A material layer of the insulating capping layer structures 160, such as silicon nitride, is formed above the substrate 100 shown in FIG. 2 after the bit lines 130 and the spacers 140 on their side walls have been etched back to remove portions thereof in the height direction. As shown in FIG. 3, a portion of the material layer of the insulating capping layer structures 160 in the height direction is then removed along the vertical direction (Y-direction) by an etching process, such as a dry etching process, so that the top surfaces of the insulating capping layer structures 160 covering the plurality of bit lines 130 and the spacers 140 on their side walls are lower than the top surface of the contact material layer 150 on both sides of the insulating capping layer structures 160, as shown in FIG. 4. Then, the contact material layer 150 is etched back to remove portions thereof in the height direction, thereby forming contact structures 151 within the gaps between adjacent spacers 140, with the top surfaces of the contact structures 151 being lower than the top surfaces of the bit lines 130, as shown in FIG. 5.

Then, a silicide layer 170 formed on the contact structures 151, pad structures 180 formed on the silicide layer 170, and isolation structures 190 arranged between adjacent pad structures 180 and being in direct contact with the insulating capping layer structures 160 and the spacers 140 are sequentially formed above the contact structure 151. In one embodiment, the pad structure 180 may include a first pad layer 181 and a second pad layer 182 that are stacked sequentially from bottom to top; where the first pad layer 181 conformally covers the contact structure 151, the insulating capping layer structure 160 and the spacer 140, and the second pad layer 182 is located on the first pad layer 181. Furthermore, the material of the first pad layer 181 may include a conductive barrier material such as titanium and/or titanium nitride (TiN), tantalum (Ta) and/or tantalum oxide (TaN), and in one embodiment the material of the first pad layer 181 is titanium nitride (TiN), but is not limited thereto. The material of the second pad layer 182 may include a metal such as tungsten (W), copper (Cu), aluminum (Al), titanium (Ti), tantalum (Ta), nitrides, silicides, alloys, and/or composite layers of the aforementioned materials, and in one embodiment the material of the second pad layer 181 is, but not limited to, tungsten (W).

It should be noted that, in the embodiments of the present application, different isolation structures 190 may be in contact with different positions of the second portions 162 of corresponding insulating capping layer structures 160. For example, in the partial enlarged view shown in FIG. 7, among a plurality of isolation structures 190, there may be at least one isolation structure 190 having a bottom surface higher than the bottom surface of the insulating capping layer structure 160 with which the isolation structure 190 is in direct contact. That is, there is at least one isolation structure 190 having a bottom surface higher than the bottom surface (in direct contact with the top surface of the second spacer 142 of the spacer 140) of the second portion 162 of the insulating capping layer structure 160 with which the isolation structure 190 is in direct contact, thereby resulting in a height difference H1 between the two bottom surfaces in the vertical direction (Y-direction), where H1 > 0. In other embodiments of the present application, such as the partially enlarged view shown in FIG. 8, at least one of the plurality of isolation structures 190 may have a bottom surface lower than the bottom surface of the insulating capping layer structure 160 with which the isolation structure 190 is in direct contact. That is, at least one isolation structure 190 may have a bottom surface that is lower than (or flush with) the bottom surface of the second portion 162 of the insulating capping layer structure 160 with which the isolation structure 190 is in direct contact, but this is not limited thereto.

In summary, the semiconductor device of the present application includes a plurality of spacers located on the side walls of a plurality of bit lines, and insulating capping layer structures covering the plurality of bit lines and the spacers, where the insulating capping layer structure includes a first portion arranged on the bit line and at least one second portion located within the spacer, thereby proposing a new structure for a semiconductor device and achieving the objective of improving both the performance and reliability of the semiconductor device.

It should be noted that, in this discourse, relational terms such as “first” and “second” are used merely to distinguish one entity or operation from another, and do not necessarily indicate or imply that any actual relationship or sequence exists between these entities or operations. Furthermore, the terms “including”, “comprising” or any other variants thereof are intended to cover non-exclusive inclusion, so that a process, method, article or apparatus including a series of elements not only includes those elements, but also includes other elements not specifically listed, or elements inherent in the process, method, article or apparatus. Without further limitation, an element defined by the statement “includes a...” does not exclude the presence of additional identical elements in a process, method, item, or apparatus that includes the element.

All embodiments in the present specification are described in a related manner, and the same and similar parts between all embodiments may be referred to each other, and each embodiment is emphatically described with respect to the differences from other embodiments. In particular, as the embodiments relating to devices, electronic equipment and computer-readable storage media are essentially similar to the method embodiments, they are described more briefly; the relevant details may refer to the relevant sections of the description of the method embodiments.

The above embodiments are merely preferred embodiments of the present application and are not intended to limit the protection scope of the present application. Any modifications, equivalent replacements, improvements, etc. made within the spirit and principles of the present application shall be included within the protection scope of the present application.

What is claimed is:

1. A semiconductor device, comprising:
a substrate;
a plurality of bit lines, arranged on the substrate and spaced apart from each other along a horizontal direction;
a plurality of spacers, located on side walls of the bit lines respectively;
a plurality of insulating capping layer structures, covering the plurality of bit lines and the spacers, wherein each insulating capping layer structure comprises a first portion arranged on the bit line and a second portion located within the spacer;
a plurality of pad structures, wherein each pad structure is located between adjacent bit lines, covers a portion of a side wall of the spacer, and in direct contact with a top surface of the insulating capping layer structure.

2. The semiconductor device according to claim 1, wherein the spacer comprises a first spacer, a second spacer, and a third spacer that are arranged in sequence.

3. The semiconductor device according to claim 2, wherein a second portion of the insulating capping layer structure is located between the first spacer and the third spacer, and in direct contact with a top surface of the second spacer.

4. The semiconductor device according to claim 2, wherein a top surface of the first spacer and/or the third spacer is higher than the top surface of the second spacer.

5. The semiconductor device according to claim 3, wherein a material of the insulating capping layer structure and a material of the third spacer are the same.

6. The semiconductor device according to claim 1, wherein an outer edge of the insulating capping layer structure and an outer edge of the spacer are aligned in a vertical direction.

7. The semiconductor device according to claim 1, further comprising:
a plurality of isolation structures, wherein each isolation structure is arranged between adjacent pad structures and in direct contact with the insulating capping layer structure and the spacer.

8. The semiconductor device according to claim 7, wherein at least one of the isolation structures is in direct contact with a top surface of the second portion of the insulating capping layer structure.

9. The semiconductor device according to claim 7, wherein a bottom surface of at least one of the isolation structures is lower than a bottom surface of the insulating capping layer structure with which the isolation structure is in direct contact.

10. The semiconductor device according to claim 1, wherein bottom surfaces of a plurality of second portions in the same insulating capping layer structure are located at different horizontal levels.

11. The semiconductor device according to claim 1, wherein a width of the insulating capping layer structure in the horizontal direction is greater than a width of the bit line in the horizontal direction.

12. A semiconductor device, comprising:
a substrate, comprising a plurality of active regions defined by trench isolations;
a plurality of bit lines, arranged on the substrate and spaced apart from each other along a horizontal direction; wherein each bit line comprise a metal layer and an insulating layer formed in sequence from bottom to top;
a plurality of spacers, wherein each spacer comprises a first spacer, a second spacer, and a third spacer stacked in sequence, arranged on the opposite side walls of the bit line;
a plurality of insulating capping layer structures, wherein each insulating capping layer structure simultaneously contacts a top of the insulating layers of the bit lines, a top and a side wall of the first spacers, a top of the second spacer, and a top and a side wall of the third spacer, wherein a portion of the insulating capping layer structure in direct contact with the second spacer has a lowest bottom surface;
a plurality of pad structures, wherein each pad structure is located between adjacent bit lines, covers a portion of a side wall of the spacer, and in direct contact with top surface of the insulating capping layer structure.

13. The semiconductor device according to claim 12, wherein a width of the insulating capping layer structure in a horizontal direction is greater than a width of insulating layer of the bit line in the horizontal direction.

14. The semiconductor device according to claim 12, wherein an outer edge of the insulating capping layer structure and an outer edge of the third spacer are aligned in a vertical direction.

15. The semiconductor device according to claim 12, further comprising:
a plurality of contact structures, wherein each contact structure is arranged on the substrate and connects the active region and the pad structure.

16. The semiconductor device according to claim 12, further comprising:
a plurality of isolation structures, wherein each isolation structure is arranged between adjacent pad structures and in direct contact with the insulating capping layer structure and the spacer.

17. The semiconductor device according to claim 16, wherein the top surface of the insulating capping layer structure is lower than the top surface of the isolation structure.

18. The semiconductor device according to claim 12, wherein the pad structure comprises a first pad layer and a second pad layer stacked sequentially from bottom to top, wherein the first pad layer is in direct contact with the cover layer structure and the spacer.

19. The semiconductor device according to claim 12, wherein the insulating capping layer structure comprises a first portion arranged on the bit line and a second portion located within the spacer.

20. The semiconductor device according to claim 12, wherein a top surface of the first spacer
and the third spacer is higher than the top surface of the second spacer.
